(19) United States
(12) Patent Application Publication
(10) Pub. No.: US 2018/0261570 A1
(43) Pub. Date: Sep. 13, 2018

(54) METHODS AND SYSTEMS FOR PARALLEL ASSEMBLY, TRANSFER, AND BONDING OF FERROMAGNETIC COMPONENTS

(71) Applicant: SelfArray, Inc., Troy, NY (US)

(72) Inventor: Mark DURNIAK, Troy, NY (US)

(73) Assignee: SelfArray, Inc., Troy, NY (US)

(21) Appl. No.: 15/916,982

(22) Filed: Mar. 9, 2018

Related U.S. Application Data
(60) Provisional application No. 62/470,515, filed on Mar. 13, 2017.

(51) Int. Cl. H01L 23/00; H01L 33/62; H01L 33/00

(52) U.S. Cl. CPC H01L 24/97; H01L 24/27; H01L 2224/95144; H01L 33/005; H01L 2224/95122; H01L 33/62

(57) ABSTRACT

Methods of and systems for assembling a plurality of ferromagnetic components into a grid-array are provided. One method includes applying a vibratory force to a magnetic stage, the magnetic stage comprising a plurality of magnets and spacers arranged in an array; depositing a plurality of ferromagnetic components, each having a ferromagnetic strip, onto the magnetic stage, the vibratory force distributing the plurality of the ferromagnetic components substantially evenly across a surface of the magnetic stage, and wherein the vibratory force aligns at least one of the plurality of ferromagnetic components with a node of maximum magnetic field strength of the magnetic stage; and removing a set of the plurality of ferromagnetic components that are not in a node of maximum magnetic field strength through physical inversion of the magnetic stage.

### CROSS-REFERENCE TO RELATED APPLICATION

This application claims priority benefit under 35 U.S.C. § 119(e) to U.S. Provisional Application No. 62/470,515, filed 13 Mar. 2017, and entitled METHODS AND SYSTEMS FOR PARALLEL ASSEMBLY, TRANSFER, AND BONDING OF FERROMAGNETIC COMPONENTS, the entirety of which is incorporated herein by reference in its entirety.

### FIELD OF THE INVENTION

The present invention relates to methods of assembling ferromagnetic components into a grid array and more particularly, to parallel assembly of light emitting diode dies into a grid array.

### BACKGROUND

Current methods of assembling components, such as light emitting diodes (LEDs), can be slow and incapable of manipulating very small components. For larger scale displays, assembly time of LED components increases quadratically as the pixel pitch decreases. The assembly throughput time and associated machine costs can determine the overall production volume and cost of the display.

Therefore, it may be desirable to develop methods of parallel assembly to increase throughput and handle components more efficiently and effectively.

### BRIEF SUMMARY

The shortcomings of the prior art are overcome and additional advantages are provided through the provisions, in one aspect, a method that includes, for instance: applying a vibratory force to a magnetic stage, the magnetic stage comprising a plurality of magnets and spacers arranged in an array; depositing a plurality of ferromagnetic components, each having a ferromagnetic strip, onto the magnetic stage, the vibratory force distributing the plurality of the ferromagnetic components substantially evenly across a surface of the magnetic stage, and wherein the vibratory force aligns at least one of the plurality of ferromagnetic components with a node of maximum magnetic field strength of the magnetic stage; and removing a set of the plurality of ferromagnetic components that are not in a node of maximum magnetic field strength through physical inversion of the magnetic stage.

In another embodiment, disclosed is a system for assembling a plurality of ferromagnetic components, the system including, for instance: a magnetic stage including a plurality of magnets and spacers arranged in an array; a vibration source configured to apply a vibratory force to the magnetic stage, the vibratory force distributing a plurality of ferromagnetic components substantially evenly across a surface of the magnetic stage, wherein the vibratory force aligns at least one of the plurality of ferromagnetic components with a node of maximum magnetic field strength of the magnetic stage; means for physically inverting the magnetic stage in order to remove a set of the plurality of ferromagnetic components that are not in a node of maximum magnetic field strength.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a method of assembling a plurality of ferromagnetic components, in accordance with one or more aspects of the present invention;

FIG. 2 depicts one embodiment of a method of creating a magnetic stage wherein creating nodes of maximum magnetic field strength along magnet intersection edges, in accordance with one or more aspects of the present invention;

FIG. 3 depicts a top view of one embodiment of a ferromagnetic component, in accordance with one or more aspects of the present invention;

FIG. 4 depicts a top view of one embodiment of a ferromagnetic component LED, in accordance with one or more aspects of the present invention;

FIG. 5 depicts a top view of one embodiment of a system including a magnetic stage and ferromagnetic components in both proper and misoriented positions, in accordance with one or more aspects of the present invention;

FIG. 6 depicts a top view of one embodiment of a system including a magnetic stage and ferromagnetic components with two overlapping ferromagnetic components on one node of maximum magnetic field strength, in accordance with one or more aspects of the present invention;

FIG. 7 depicts a top view of one embodiment of a system including a magnetic stage and an array of ferromagnetic components after having inverted the stage to remove all misoriented components, in accordance with one or more aspects of the present invention; and

FIG. 8A depicts a top view and FIG. 8B a cross-sectional elevation view of one embodiment of a system including a transfer substrate brought over the stage and assembled ferromagnetic components, and shows the transfer substrate being lowered into contact with the ferromagnetic components, in accordance with one or more aspects of the present invention;

FIG. 8 a cross-sectional elevation view of a system including lifting the transfer substrate along with the adhered ferromagnetic components.

FIG. 10 depicts a top view of one embodiment of a system including final substrate containing a back substrate and electrical contacts, in accordance with one or more aspects of the present invention;

FIG. 11A depicts a top view and FIG. 11B a cross-sectional elevation view of one embodiment of a system including a transfer substrate with adhered ferromagnetic components aligned to the final substrate, and the lowering of the transfer substrate with the ferromagnetic components into contact with the final substrate contact pads, and removal of the transfer substrate leaving behind the ferromagnetic components on the final substrate, in accordance with one or more aspects of the present invention;

FIG. 12 depicts a top view of one embodiment of a system including final substrate containing an array of connected ferromagnetic components, in accordance with one or more aspects of the present invention;

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are methods and systems of assembling ferromagnetic components into a grid array. Advantageously, the methods allow for efficient assembly of components with a high accuracy rate.

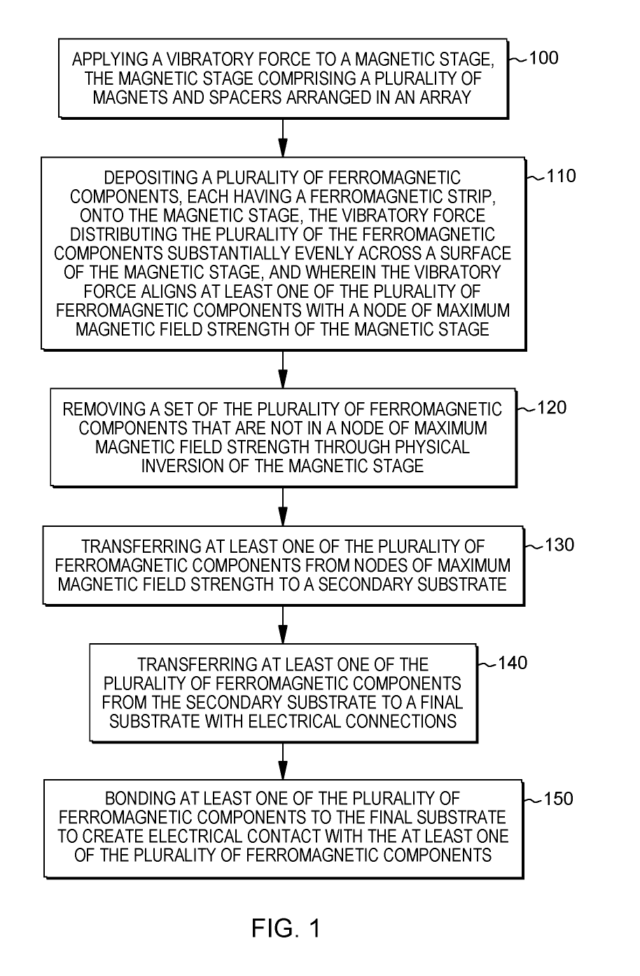

In one aspect, in one embodiment, as shown in FIG. 1, a method of assembling a plurality of ferromagnetic components into a grid array may include applying a vibratory force to a magnetic stage, the magnetic stage comprising a plurality of magnets and spacers arranged in an array 100; depositing a plurality of ferromagnetic components, each having a ferromagnetic strip, onto the magnetic stage, the vibratory force distributing the plurality of the ferromagnetic components substantially evenly across a surface of the magnetic stage, and wherein the vibratory force aligns at least one of the plurality of ferromagnetic components with a node of maximum magnetic field strength of the magnetic stage 110; removing a set of the plurality of ferromagnetic components that are not in a node of maximum magnetic field strength through physical inversion of the magnetic stage 120; transferring at least one of the plurality of ferromagnetic components from nodes of maximum magnetic field strength to a secondary substrate 130; transferring at least one of the plurality of ferromagnetic components from the secondary substrate to a final substrate with electrical connections 140; and bonding at least one of the plurality of ferromagnetic components to the final substrate to create electrical contact with the at least one of the plurality of ferromagnetic components 150.

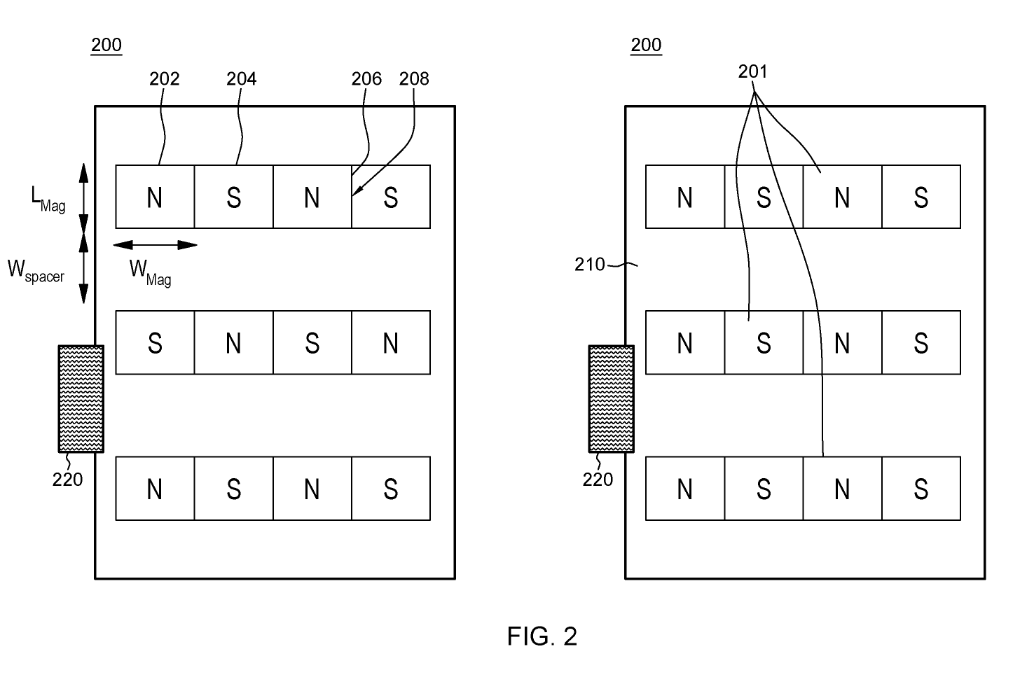

An example of a system including a magnetic stage 200 comprised of rows of magnets with alternating polarity 202 (N) and 204 (S) separated by spacers 210 useful for the methods disclosed herein is depicted in FIG. 2. For instance, the magnetic stage 200 may include a plurality of magnets 201, separated by spacers 210 to create an array, including but not limited to rows of magnets 201 with alternating north pole and south pole magnets 202 and 204 respectively. The magnets 201 can include ferrite or ceramic, as well as rare earth magnets such as neodymium or samarium-cobalt magnets, or any other strong magnet now known or later developed. The magnets 201 may also include magnetic domains created via printing onto a magnetic polymer or magnetic domains created in by using localized electromagnetic fields. The dimensions of the magnets or magnetic domains may be the same or different materials for each of the plurality of magnets 201, and may be of the same or different sizes. As seen on the left, rows of magnets 201 may be arranged with alternating north poles 202 and south poles 204 between rows, or as on the right, with north poles 202 and south poles 204 aligned between rows. Regions of high magnetic field strength 206 are formed along edges of adjacent magnets of opposite polarity, forming nodes of maximum magnetic field strength 208 at the center of these edges. The spacers 210 can include non-ferromagnetic materials or ferromagnetic materials, and may be approximately equal in length and width to the length and width of the rows of magnets 201. When the spacers 210 include non-ferromagnetic materials, the offset polarity of magnets 201 illustrated on the left can assist in assembly, as alternating rows will repel one another. When the spacers 210 include ferromagnetic materials, either polarity as illustrated on the left and right, may be utilized. A vibratory force may be applied to the magnetic stage 200 by a vibration source 220, which may include, for instance, a transducer or a motor capable of applying a vibratory source when in contact with the magnetic stage 200, or integrated into a hopper as will be described in more detail.

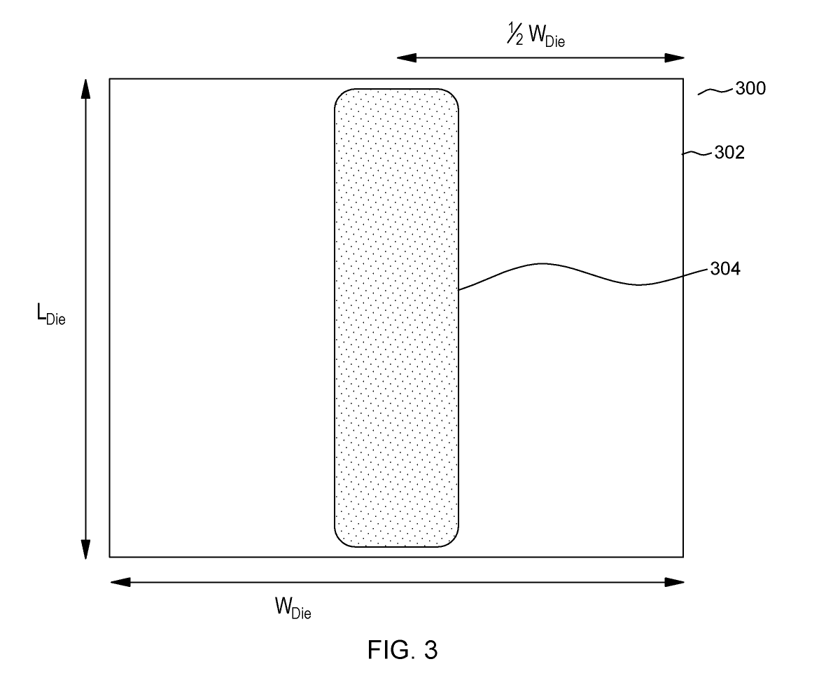

Turning to FIG. 3, illustrated is an example of a ferromagnetic component 300 for depositing onto the magnetic stage 200, including a non-ferromagnetic die 302 and a thin strip of ferromagnetic material 304. For instance, the ferromagnetic material can include nickel, iron, steel, or any other ferromagnetic material. The location and orientation of the ferromagnetic strip 304 may be anywhere on the face of the non-ferromagnetic die 302. For instance, a thin ferromagnetic strip 304 may be centered along the width axis of the non-ferromagnetic die and span the length of the non-ferromagnetic die. The non-ferromagnetic die 302 may include a semiconductor material, such as Si, GaN, Sapphire, GaAs, or any other semiconductor material.

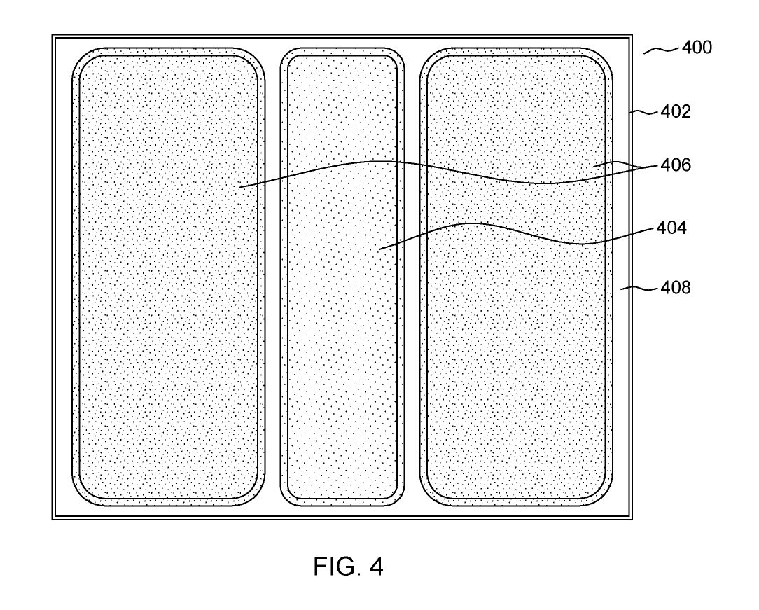

Illustrated in FIG. 4 is one specific example of a ferromagnetic component 300, for instance a ferromagnetic LED component 400. The ferromagnetic LED component 400 may include a non-ferromagnetic LED die 402 and a thin strip of ferromagnetic material 404 as depicted in FIG. 4. For instance, the ferromagnetic strip 404 may contain Ni and can operate as the p-type contact of the LED, the two adjacent metal pads 406 can include non-ferromagnetic materials, creating the n-type contact of the LED, and insulating oxide 408 can be used to prevent shorting between the two contacts. The location and orientation of the ferromagnetic strip 404 may be anywhere on the face of the non-ferromagnetic LED die 400. However, it is beneficial for the die to have 180 degree rotational symmetry (also known as reflection symmetry about the halfway point of the width axis).

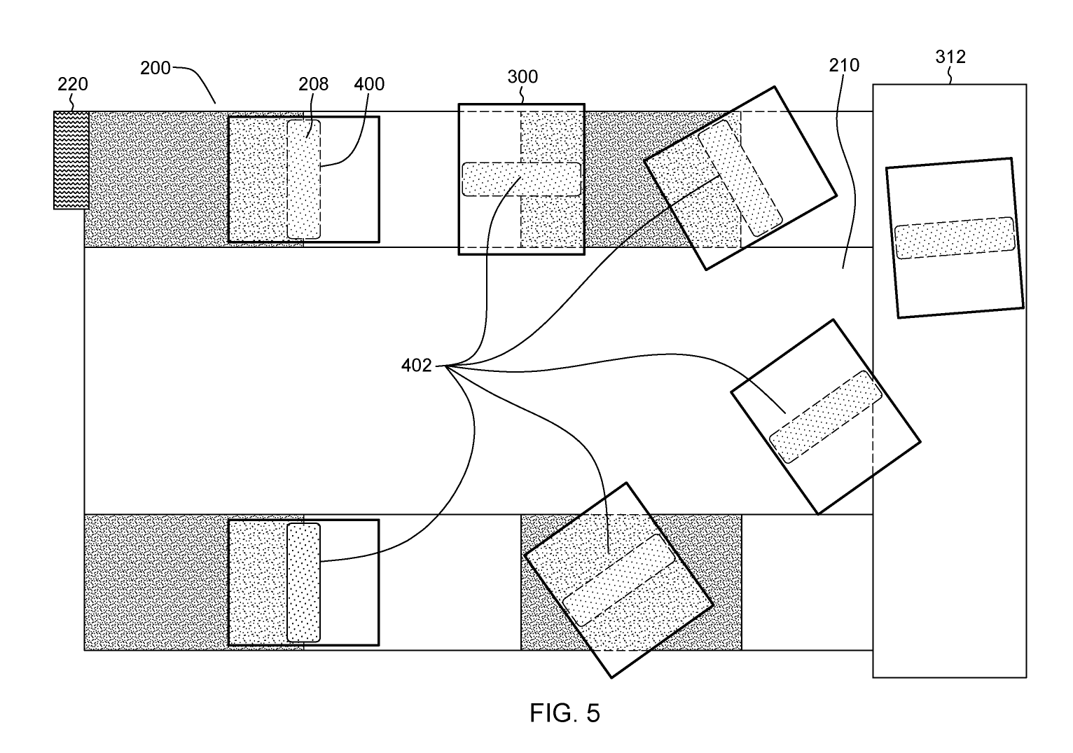

As seen in FIG. 5, in some embodiments a plurality of ferromagnetic components 300, which can include some or all of ferromagnetic LED components 400, may be deposited, using for instance a hopper 312 or similar device. The hopper 312 can include its own vibration source 220 (not illustrated), or it may be in contact with the magnetic stage 200, which will translate the vibrations from vibration source 220 to the hopper 312. Thus, the vibration source 220 should be sufficient to move and distribute the plurality of ferromagnetic components 300 substantially evenly across the surface of the magnetic stage 200, which may be assisted by moving the hopper 312 across and over the surface and releasing a portion of the ferromagnetic components 300 as it travels. Alternatively, the vibratory force may distribute all or some of the ferromagnetic components 300 from one or more deposition areas. The vibration source 220 should also be of sufficient strength to align at least one of the ferromagnetic components into a node of maximum magnetic field strength 208 of the magnetic stage 200. In some embodiments, the center of the edge between adjacent magnets of opposite polarity 202 and 204 will become a node of maximum magnetic field strength 208 owing to the magnetic properties and field created by the opposing magnets arranged accordingly. In some embodiments, the vibratory force is applied to the magnetic stage 200 prior to depositing the plurality of ferromagnetic components 300 so that the ferromagnetic components 300 will evenly distribute during the deposition. However, in alternative embodiments, the vibratory force may be applied following the deposition, allowing for the ferromagnetic components 300 to be evenly disbursed by hand or machine, and then applying the vibratory force to redistribute the components.

Still referring to FIG. 5, once at least one of the plurality of ferromagnetic components 300 are oriented with their thin ferromagnetic strip 304 aligned parallel to the region of high magnetic field strength 206 and centered at the node of maximum magnetic field strength 208, in some embodiments some or all of the nodes 208 may have a ferromagnetic component 300 aligned over the node 208, any ferromagnetic components 300 which are not located above, and in some embodiments aligned with, a node 208 can be removed. In some embodiments, the ferromagnetic strip 304 is of a material and dimension chosen to correspond to a size and strength of the magnets or magnetic domains 201, such that those components whose ferromagnetic strips 304 are facing the magnetic stage 200, aligned parallel to the region of high magnetic field strength 206, and centered at the node of maximum magnetic field strength 208 experience a magnetic attraction force 400greater than the force due to gravity 402; and such that ferromagnetic components of any other orientation wherein the ferromagnetic strips are not facing the magnetic stage 200, or oriented parallel to the region of high magnetic field strength 206, or centered at the node of maximum magnetic field strength 208 experience a magnetic attraction force weaker than the force due to gravity 402.

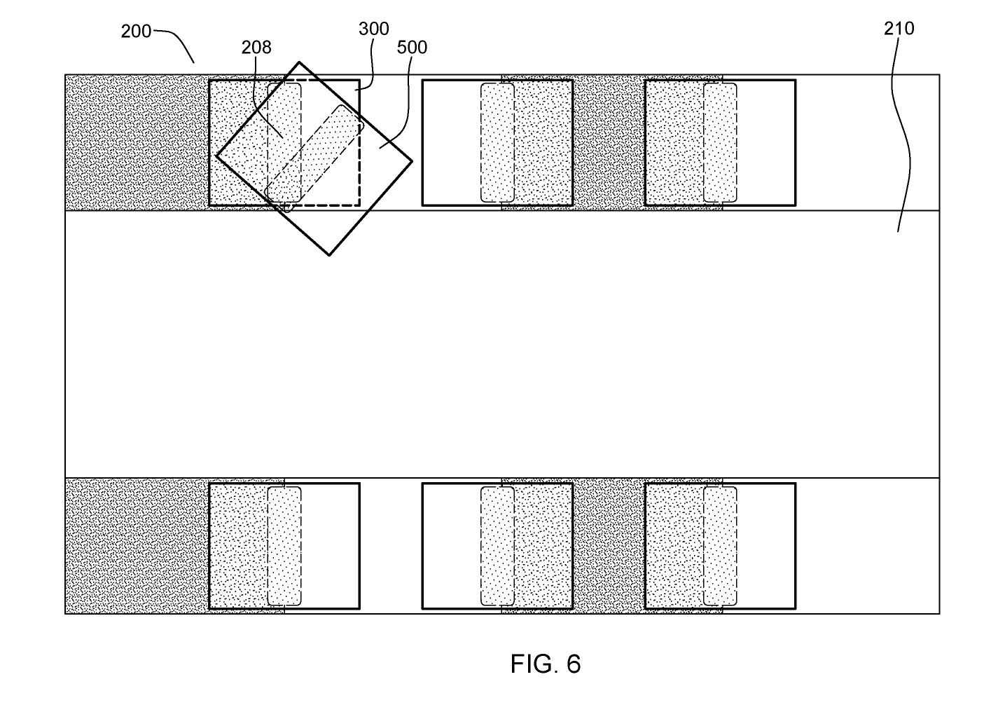

In some embodiments, as shown in FIG. 6, a second ferromagnetic component 500 may occupy the same node of maximum magnetic field strength 208 as another component 300. In this case, the ferromagnetic component 300 closest to the stage 200 will experience a magnetic attractive force greater than that due to gravity whereas the second ferromagnetic component 500 will experience a force weaker than that due to gravity, allowing for easy removal of stacked ferromagnetic components 300.

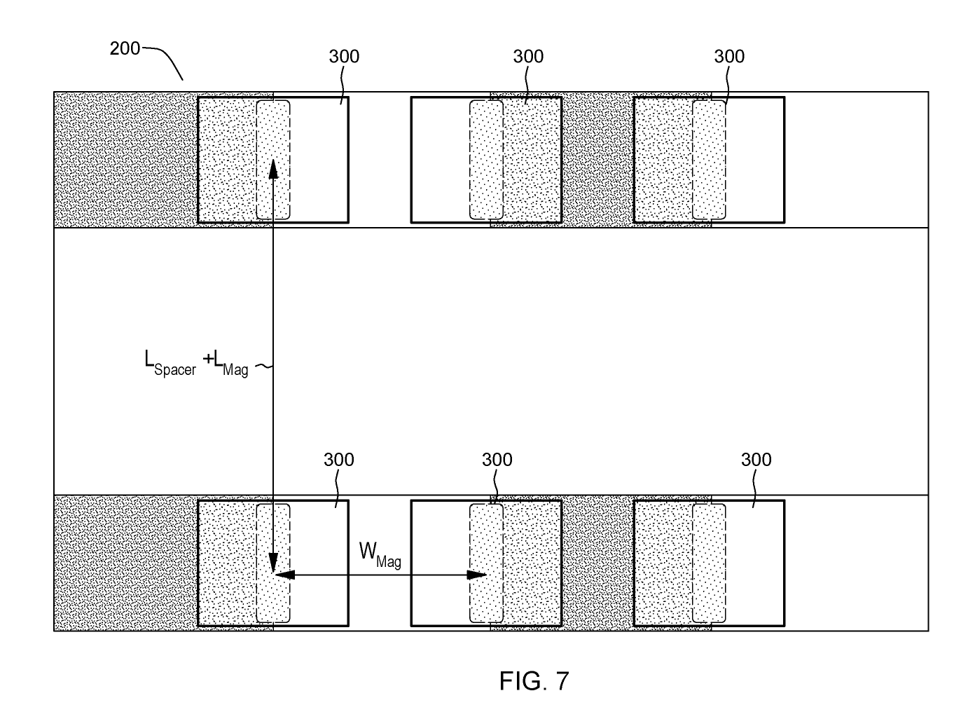

In some embodiments the magnetic stage 200 can be inverted, or flipped upside down, and gravity can assist in removing any ferromagnetic components 300, including any second ferromagnetic components 500 (FIG. 6), which are not experiencing magnetic attractive forces greater than the force to due gravity. At least one of a plurality of the ferromagnetic components 300 will be located in node(s) of maximum magnetic field strength 208, as illustrated in FIG. 7. Any now known or later developed means may be used to invert the magnetic stage 200, including a wafer processing machine. In some embodiments, the remaining ferromagnetic components 300 form a grid-array, with one, some, or all of the nodes of maximum magnetic field strength 208 being occupied.

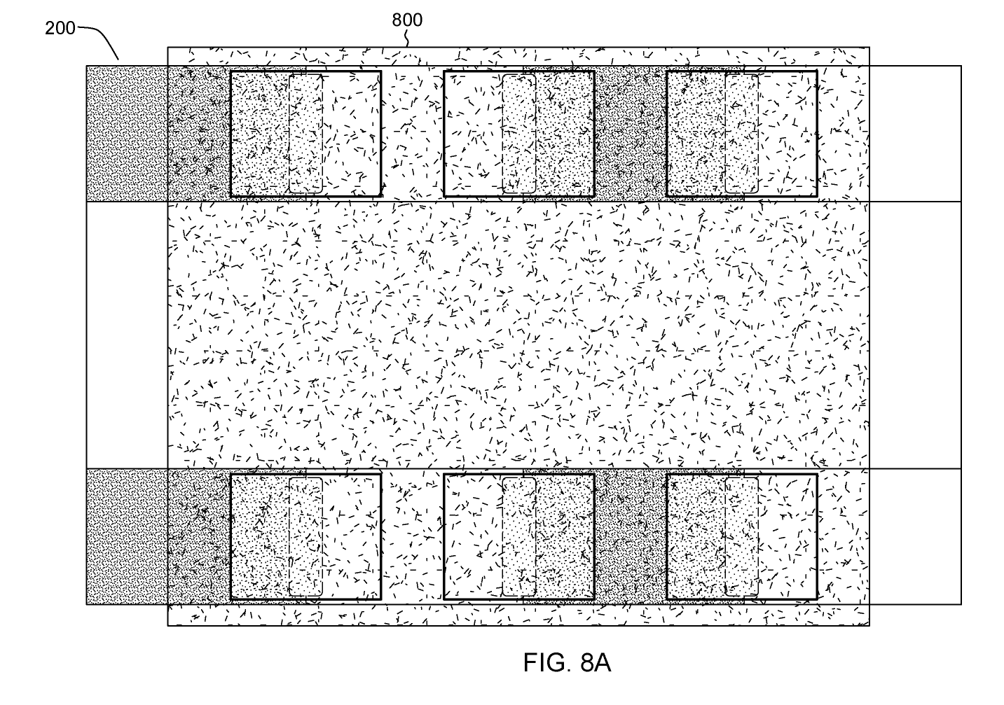

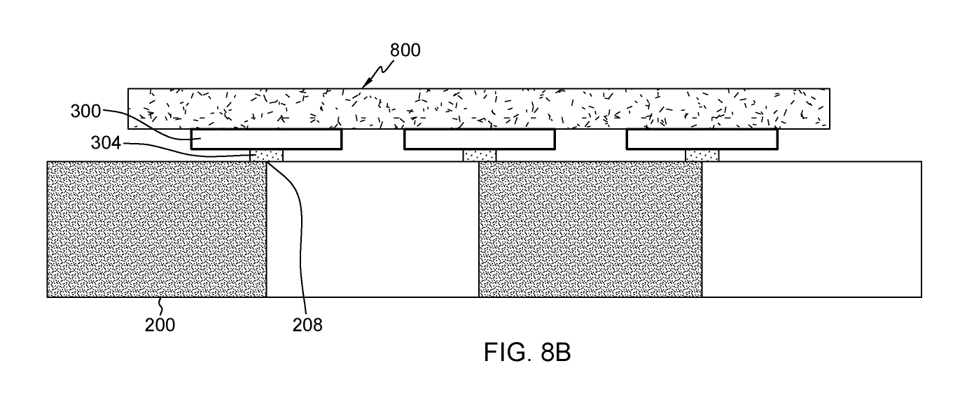

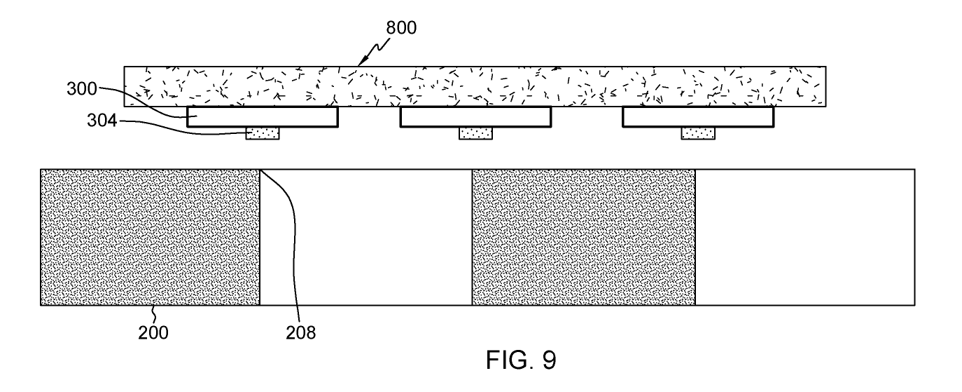

Turning to FIG. 8A, in some embodiments, at least one of the plurality of ferromagnetic components 300 located in nodes of maximum magnetic field strength 208 can be adhered to a secondary, or transfer substrate 800 as seen in FIG. 8. A transfer substrate can be brought in over the surface and pressed into the components. This substrate can be rigid or flexible, and the attractive force between the components and the transfer substrate can be greater than the magnetic attractive force experienced by the components. The components may be attracted and attached to the secondary substrate via polymer adhesives, vacuum suction, electrostatic force, or any other bonding or adhering technique known to those skilled in the state of the art. FIG. 8B shows the transfer substrate 800 contacting the remaining ferromagnetic components 300 from a side view.

Turning to FIG. 9, in some embodiments, the secondary substrate 800 can be lifted, by any now known or later developed methods, taking with it at least one of the plurality of ferromagnetic components 300 adhered to it. The transfer substrate 800 can be lifted at once or rolled off or across, if a flexible substrate 800 is utilized. It should be understood that a secondary or transfer substrate 800 is not necessary in all embodiments.

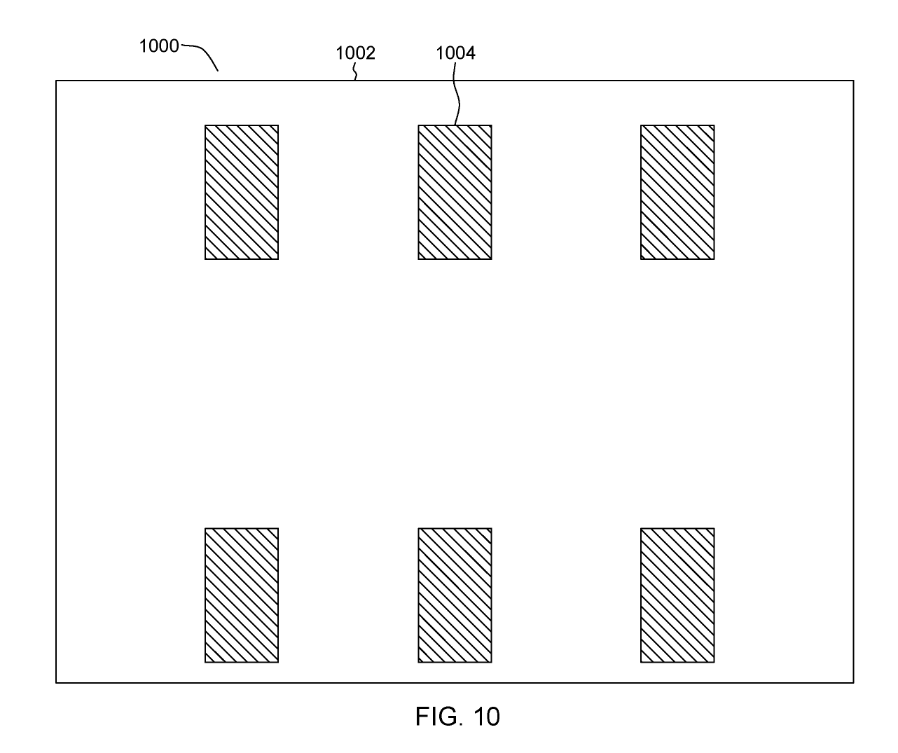

Turning to FIG. 10, in some embodiments, a final or receiving substrate 1000 for bonding with ferromagnetic components 300 (FIG. 9) may consist of a backplane or substrate 1002 with electrical contact pads 1004. The electrical contact pads 1004 can contain solder and flux, anisotropic conductive adhesive, or any other electrically bonding material known to the state of the art.

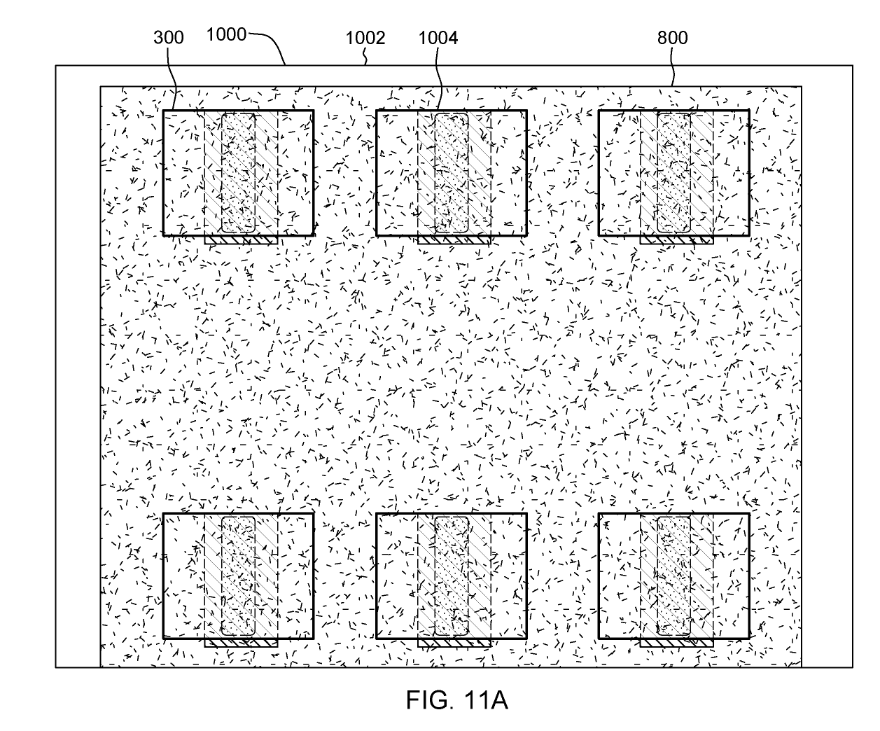

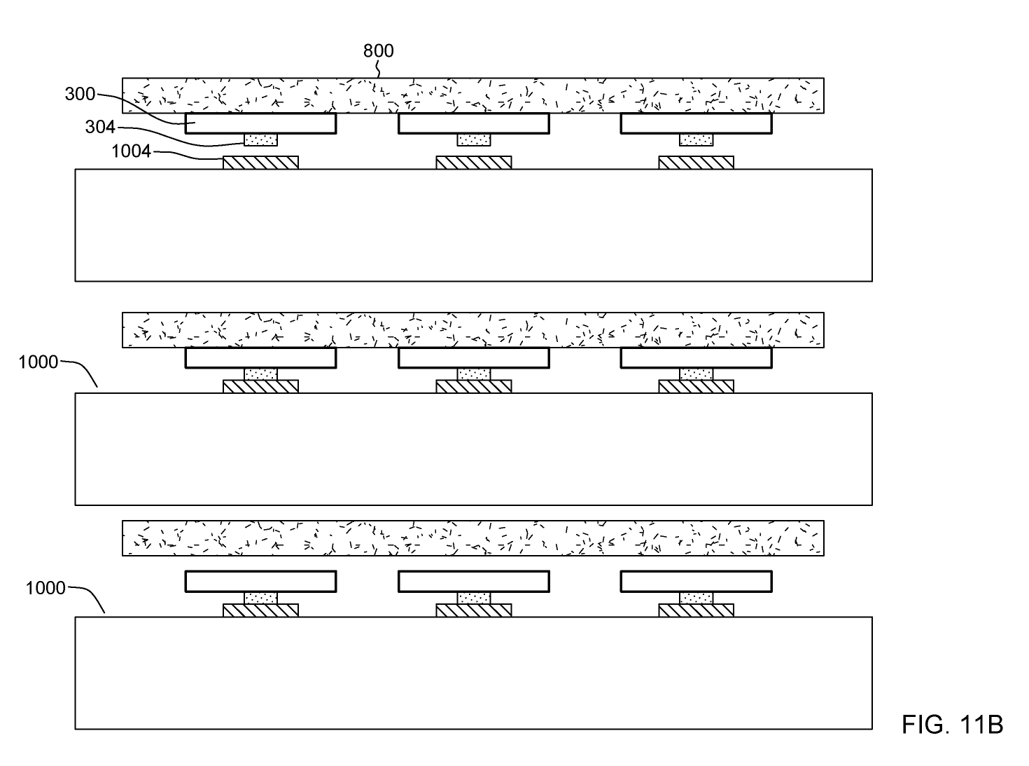

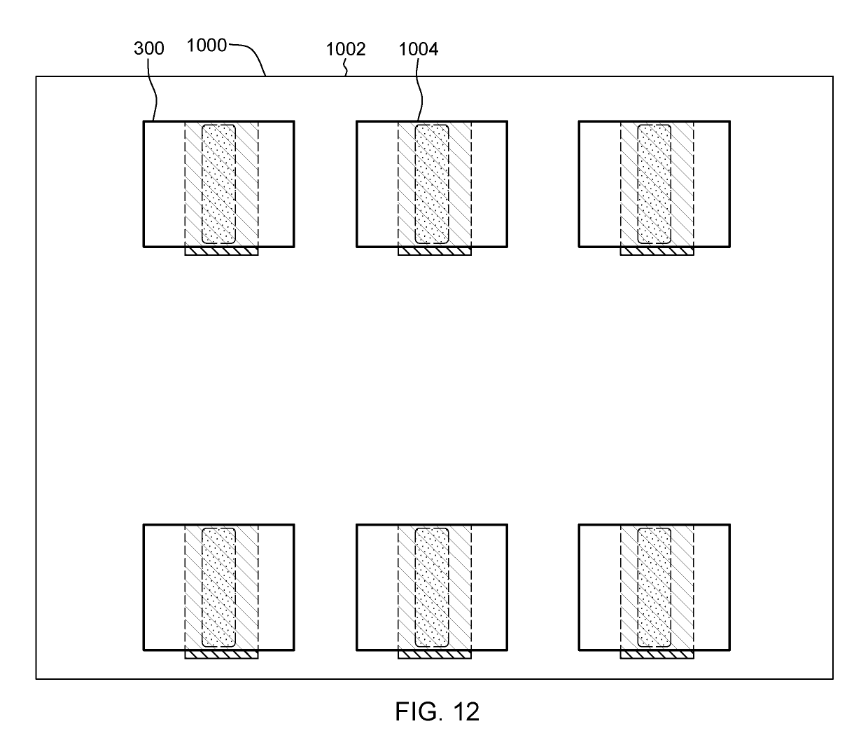

Turning to FIGS. 11A and 11B, illustrating a top view and side view respectively, in some embodiments, the transfer substrate 800 (or magnetic stage 200, not shown) is brought over the final substrate 1000 and aligned such that any contact pads on the ferromagnetic components 300 align with the contact pads 1004 on the final substrate 1000. In further embodiments, the transfer substrate 800 containing at least one of the plurality of ferromagnetic components 300 is brought down and into contact with the final substrate 1000. Upon contact of the ferromagnetic components 300 with the electrical contact pads 1004, any bonding material on the final substrate contact pads 1004 can be activated, creating an adhesion force between the contact pad 1004 and at least one of the ferromagnetic components 300. This force is chosen to be greater than the adhesion force between the ferromagnetic component 300 and the secondary substrate 800 (or magnetic stage 200). This adhesion force may also create electrical connection between the ferromagnetic components 300 and the contact pads 1004. The secondary substrate 800 (or magnetic stage 200) can then be lifted away from the final substrate leaving behind at least one of the plurality of ferromagnetic components 300, as illustrated in FIG. 12. In one embodiment, the resulting structure is a grid-array of components 300.

While the method is described above, also disclosed is a system for assembling a plurality of ferromagnetic components 300. For instance, the system can include a magnetic stage 200 including a plurality of magnets 201 and spacers 210 arranged in an array as described above in reference to FIG. 2. The system may also include a vibration source 220 configured to apply a vibratory force to the magnetic stage 200, the vibratory force distributing a plurality of ferromagnetic components 300 (FIG. 5) substantially evenly across a surface of the magnetic stage 200, wherein the vibratory force aligns at least one of the plurality of ferromagnetic components 300 with a node of maximum magnetic field strength 208 of the magnetic stage 200. The system may also include means for physically inverting the magnetic stage 200 in order to remove a set of the plurality of ferromagnetic components 300 which are not in a node of maximum magnetic field strength 208, said means including any machine capable of inverting a substrate.

The system may also include, for instance, means for transferring at least one of the plurality of ferromagnetic components 300 from nodes of maximum magnetic field strength to a secondary substrate. Also included can be a means for transferring at least one of the plurality of ferromagnetic components 300 from the secondary substrate 800 to a final substrate 1000 with electrical connections 1004, and a means for bonding at least one of the plurality of ferromagnetic components 300 to the final substrate 1000 to create electrical contact with the at least one of the plurality of ferromagnetic components, as illustrated and described above in reference to FIGS. 10-12. These means can include any wafer or substrate processing equipment capable of transporting the substrates.

Thus, a quick and efficient method and system is provided for assembling a set of components. The process is easily repeatable and can be run continuously with a feed of components.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method of assembling a plurality of ferromagnetic components, the method comprising:
applying a vibratory force to a magnetic stage, the magnetic stage comprising a plurality of magnets and spacers arranged in an array;
depositing a plurality of ferromagnetic components, each having a ferromagnetic strip, onto the magnetic stage, the vibratory force distributing the plurality of the ferromagnetic components substantially evenly across a surface of the magnetic stage, and wherein the vibratory force aligns at least one of the plurality of ferromagnetic components with a node of maximum magnetic field strength of the magnetic stage; and
removing a set of the plurality of ferromagnetic components that are not in a node of maximum magnetic field strength through physical inversion of the magnetic stage.

2. The method of claim 1, further comprising:
transferring at least one of the plurality of ferromagnetic components from nodes of maximum magnetic field strength to a secondary substrate.

3. The method of claim 2, further comprising:
transferring at least one of the plurality of ferromagnetic components from the secondary substrate to a final substrate with electrical connections;
bonding at least one of the plurality of ferromagnetic components to the final substrate to create electrical contact with the at least one of the plurality of ferromagnetic components.

4. The method of claim 1, wherein the plurality of magnets are arranged in an array of rows with alternating north poles and south poles with spacers of non-ferromagnetic material between the rows.

5. The method of claim 1, wherein the plurality of magnets are arranged in an array of rows with alternating north and south poles with spacers of ferromagnetic material between the rows.

6. The method of claim 5, wherein a dimension of the ferromagnetic strip of the plurality of ferromagnetic components and a magnetic strength of the plurality of magnets are chosen such that when the ferromagnetic strips are facing the magnetic stage, aligned parallel to the node of maximum magnetic field strength of the magnetic stage, and centered at the node of maximum magnetic field strength, the at least one ferromagnetic component experiences a first magnetic attraction force greater than a force due to gravity; and such that ferromagnetic components of any other orientation experience a second magnetic attraction force weaker than the force due to gravity.

7. The method of claim 6, wherein physical inversion of the magnetic stage causes gravity to assist in removal of any components with the second magnetic attraction force weaker than the force due to gravity.

8. The method of claim 7, wherein, following inversion of the magnetic stage, only the at least one ferromagnetic component remains on the magnetic stage.

9. The method of claim 1, wherein the vibratory force is applied following the depositing.

10. The method of claim 1, wherein the depositing utilizes a hopper in contact with the magnetic stage.

11. A system for assembling a plurality of ferromagnetic components, the system comprising:
a magnetic stage including a plurality of magnets and spacers arranged in an array;
a vibration source configured to apply a vibratory force to the magnetic stage, the vibratory force distributing a plurality of ferromagnetic components substantially evenly across a surface of the magnetic stage, wherein the vibratory force aligns at least one of the plurality of ferromagnetic components with a node of maximum magnetic field strength of the magnetic stage;
means for physically inverting the magnetic stage in order to remove a set of the plurality of ferromagnetic components that are not in a node of maximum magnetic field strength.

12. The system of claim 11, further comprising:
means for transferring at least one of the plurality of ferromagnetic components from nodes of maximum magnetic field strength to a secondary substrate.

13. The system of claim 12, further comprising:
means for transferring at least one of the plurality of ferromagnetic components from the secondary substrate to a final substrate with electrical connections;
means for bonding at least one of the plurality of ferromagnetic components to the final substrate to create electrical contact with the at least one of the plurality of ferromagnetic components.

14. The system of claim 11, wherein the plurality of magnets are arranged in an array of rows with alternating north poles and south poles with spacers of non-ferromagnetic material between the rows.

15. The system of claim 11, wherein the plurality of magnets are arranged in an array of rows with alternating north and south poles with spacers of ferromagnetic material between the rows.

16. The system of claim 15, wherein a dimension of the ferromagnetic strip of the plurality of ferromagnetic components and a magnetic strength of the plurality of magnets are chosen such that when the ferromagnetic strips are facing the magnetic stage, aligned parallel to the node of maximum magnetic field strength of the magnetic stage, and centered at the node of maximum magnetic field strength, the at least one ferromagnetic component experiences a first magnetic attraction force greater than a force due to gravity; and such that ferromagnetic components of any other orientation experience a second magnetic attraction force weaker than the force due to gravity.

17. The method of claim 16, wherein physical inversion of the magnetic stage by the means for inverting causes gravity to assist in removal of any components with the second magnetic attraction force weaker than the force due to gravity.

18. The system of claim 17, wherein, following inversion of the magnetic stage, only the at least one ferromagnetic component remains on the magnetic stage.

19. The system of claim 11, further comprising:
a hopper in contact with the magnetic stage for depositing the plurality of ferromagnetic components.

20. The system of claim 19, wherein the hopper comprises the vibration source.
